(19) United States
(12) Patent Application Publication
(10) Pub. No.: US 2009/0267140 A1
(43) Pub. Date: Oct. 29, 2009

(54) MOSFET STRUCTURE WITH GUARD RING

(76) Inventor: Fu-Yuan HSIEH, Hsinchu City (TW)

Correspondence Address: BIRCH STEWART KOLASCH & BIRCH, PO BOX 747, FALLS CHURCH, VA, 22040-0747, US

(21) Appl. No.: 12/111,797

(22) Filed: Apr. 29, 2008

(51) Int. Cl. H01L 29/78; H01L 21/336

(52) U.S. Cl. 257/328; 438/270; 257/E29.262; 257/E21.41

(57) ABSTRACT

A trench Metal-Oxide-Semiconductor Field Effect Transistor (MOSFET) structure with guard ling, includes: a substrate including an epi layer region on the top thereof a plurality of source and body regions formed in the epi layer; a metal layer including a plurality of metal layer regions which are connected to respective source and body regions forming metal connections of the MOSFET; a plurality of contact metal plugs connected to respective metal layer regions; a plurality of gate structure filled with polysilicon to be formed on top of the epi layer; an insulating layer deposited on the epi layer formed underneath the metal layer with a plurality of metal contact holes therein for contacting respective source and body regions; and a guard ring wrapping around the trench gates with contact metal plug underneath the gate metal layer

### BACKGROUND OF THE INVENTION

1. Field of the Invention

The present invention relates to a trench MOSFET structure with a guard ring and the method for manufacturing the same, and more particularly to a structure of a trench MOSFET which solves low breakdown voltage in contacted trench gate area and the method for manufacturing the same.

2. The Prior Arts

In the structure of a trench Metal-Oxide-Semiconductor Field Effect Transistor (MOSFET) or vertical transistor, the gate of the transistor is formed in a trench on top of a substrate and the source/drain regions are formed on both sides of the gate. This type of vertical transistor allows high current to pass through and channel to be turned on/off at a low voltage.

Referring to FIG. 1, a cross-sectional diagram of the structure of a trench MOSFET is shown. An N-type doping epitaxial region 105 is provided on a N+ substrate 100. A plurality of trenches 106 are formed on the N-type doping epitaxial region 105 that has lower doping concentration than the substrate 100. The surface of trenches 106 which is covered a gate oxide layer 110 thereon are filled with a polysilicon layer to form a plurality of trenched gates 115. A plurality of P-type doping regions 120 are formed on both sides of the trenched gates 115. A plurality of N+ doping regions 125 are formed in the P-type doping regions 120, and the N+ doping regions 125 are used as the source regions of the MOSFET structure. A metal layer 160 is formed on the top of the MOSFET structure and is formed as the source metal, the gate runner, and the field plate metal of the MOSFET. An insulating layer 130 is formed between the metal layer 160 and the gate structure 115 for insulating, and the contact plugs 137 are formed in the P-type doping regions 120 and a wide trench of the said trenched gates 116 for gate contact (Please change 115 to 116 for the wider trench gate in FIG. 1) (The wide trench gate 116 allows metal contact into the doped polysilicon in the trenches without shorting to the P-type doping regions 120) and are penetrated through the insulating layer 130 to contact with the metal layers 137 and 160 respectively and to be the metal connections of the MOSFET structure. A plurality of P+ heavily-doped regions 121 are formed at the bottom of the trenched gates 115. The MOSFET structure of the prior arts also has a guard ring 170 which is formed aside the P-type doping regions 120 underneath the field plate metal of the metal layer 160 of the MOSFET to increase breakdown voltage in termination. However, the structure in FIG. 1 has low breakdown voltage occurring on trench bottom of the gate contact trench 116 as result of wider trench which has deeper trench depth than the trench depth in active area. The trench depth is deeper when the trench width is wider because more open area allows more etching gas goes into trench during dry etching silicon process. When reverse bias between drain and gate/source increases, avalanche will first occur on the trench bottom of the contacted trench gate 116 because it has deeper trench gate.

The present invention provides a new structure of trench MOSFET structure with a guard ring wrapped around the contacted trench gate which improves the lack of the prior art.

### SUMMARY OF THE INVENTION

This invention provides a trench Metal-Oxide-Semiconductor Field Effect Transistor (MOSFET) with a guard ring. The MOSFET structure with guard ring, comprising: a substrate comprising an epi layer region on the top thereof; a plurality of source and body regions formed in the epi layer; a metal layer comprising a plurality of metal layer regions which are connected to respective source and body regions forming metal connections of the MOSFET; a plurality of contact plugs connected to respective metal layer regions; a plurality of gate structure filled with polysilicon to be formed on top of the epi layer; an insulating layer deposited on the epi layer formed underneath the metal layer with a plurality of metal contact holes therein for contacting respective source and body regions; and a guard ring wrapping around the gates underneath the metal layer, wherein the contact plugs are corresponding to the source and the body regions

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional diagram depicting a trench MOSFET structure with a guard ring;

FIGS. 2A-2F are cross-sectional diagrams illustrating forming a trench MOSFET structure with guard ring on a substrate in accordance with an embodiment of the present invention; and

FIG. 3 is a cross-sectional diagram illustrating the trench MOSFET structure with guard ring in accordance with another embodiment of the present invention.

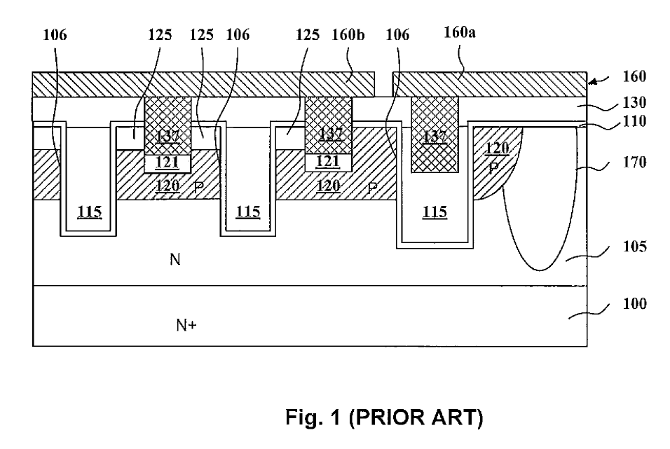

### DETAILED DESCRIPTION OF THE PREFERRED EMBODIMENT

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

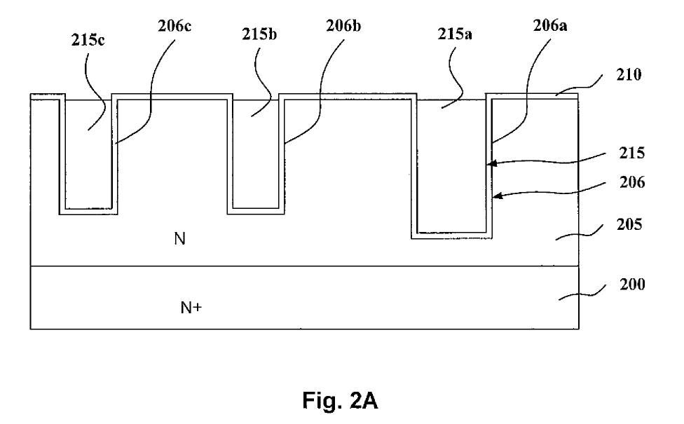

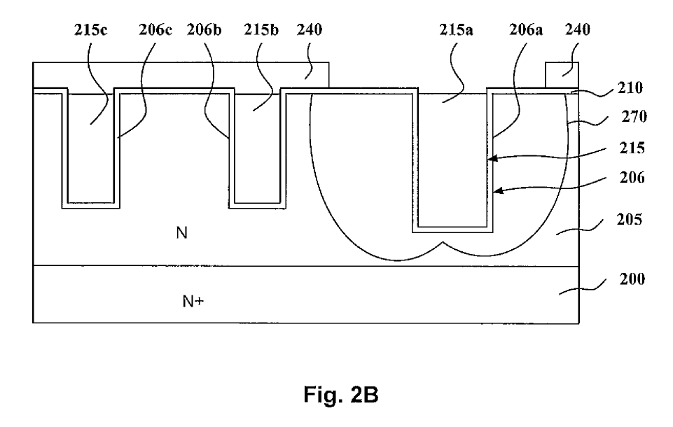

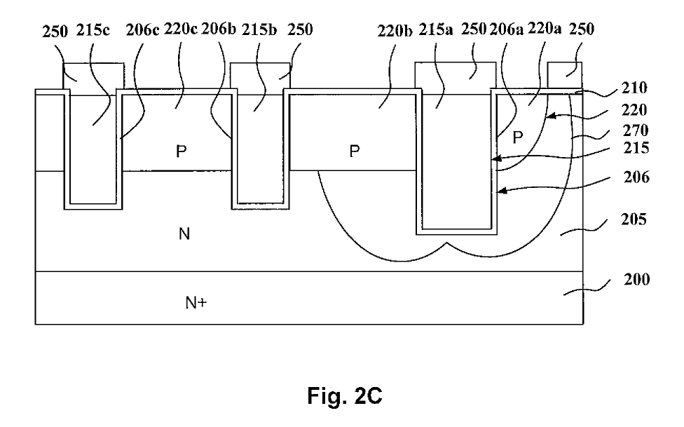

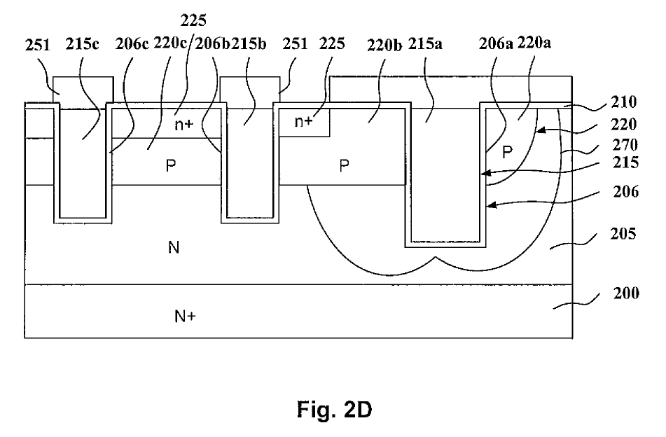

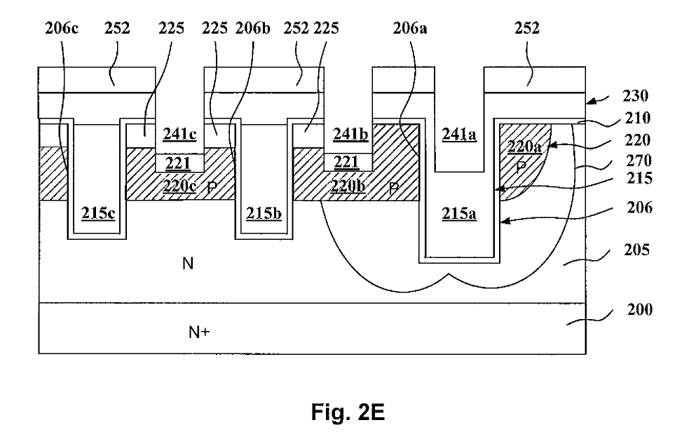

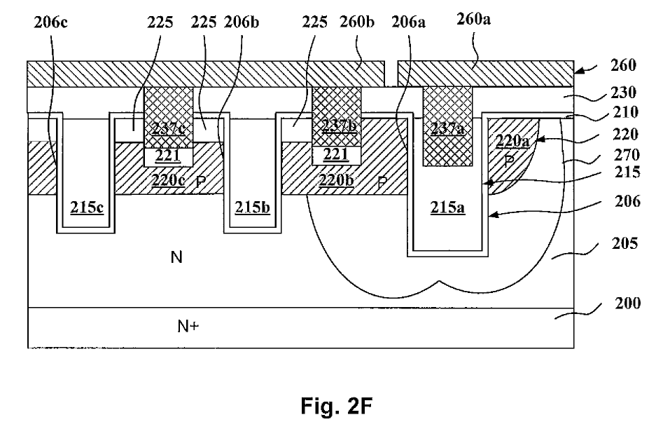

Referring to FIG. 2A, an N+ doped substrate 200 having a N-type doping epi layer region 205 thereon is provided. Lithography and dry etching processes are performed to form a plurality of trenches 206 in the N-type epi layer 205. The trenches 206 comprise a first trench 206a, a second trench 206b, and a third trench 206c, and the first trench 206a is deeper and wider than both of the second trench 206b and third trench 206c. Then, a deposition or thermally grown process is performed to form a silicon oxide layer on the surface of the N-type doping region 205 and the trenches 206, which acts as a gate oxide layer 210 of a trench MOSFET. Prior to the gate oxide layer 210 is formed, a sacrificial oxide is grown and wet etched for removal silicon damage along the trench 206 surface induced by the dry trench etch. At last, a doped polysilicon layer is formed on the gate oxide layer 210 and filled in the trenches 206 by a deposition process. Thereafter, the doped polysilicon layer on the gate oxide layer 210 is removed by a dry etching process or a CMP (chemical-mechanical polishing process) and the doped polysilicon layer on the each trench 206 is removed by a polysilicon etching back process, and a plurality of gate structures 215 of the trench MOSFET in the trench are formed. The gate structure 215 comprises a first gate 215a, a second gate 215b, and a third gate 215c which are respectively formed on the first trench 206a, the second trench 206b, the third trench 206c.

Referring to FIG. 2B, a second mask 240 is formed over the gate oxide layer 210 and the gate structure 215 by lithography to define a doping zone. Then, a guard ring 270 are formed in the N-type doping region 205 by an ion implantation and diffusion processes. After processes of forming the guard ring 270, the second mask 240 is removed. The guard ring 270 surrounds the first gate 215a of the gate structure 215 while the doping zone of the guard ring 270 is covered the first gate 215a and the doping depth of the guard ring 270 is deeper than the first gate 215a. Moreover the guard ring 270 is corresponding to the source, the gate, and drain regions of the trench MOSFET.

Referring to FIG. 2C and FIG. 2D, a third mask 250 is formed to define another doping zone, and a plurality of P-body regions 220 are formed in the N-type doping region 205 by an ion implantation, the third mask 250 removal and diffusion processes. After that, a forth mask 251 (see FIG. 2D) is formed so as to facilitate formation of N+ doping regions 225 in the second P-body region 220b and third P-body region 220c of the P-body regions 220 by ion implantation and thermal diffusion processes after the forth mask 251 is removed. The N+ doping regions 225 are corresponding to the source of the trench MOSFET.

Referring to FIG. 2E, an insulating layer 230 is formed on the gate oxide layer 210 and the gate structure 215. This insulating layer 230 is a silicon dioxide layer formed by a deposition process. After the deposition of the insulating layer 230, a fifth mask 252 is formed on the surface of the insulating layer 230 by lithography. This fifth mask 252 defines the locations of metal contacts of the trench MOSFET. Thereafter, a dry etching process is performed by using the fifth mask 252 as the etching mask, such that metal contact holes 241a, 241b,and 241c are formed in the insulating layer 230, the N+ sources 225, the P-body regions 220, and the first gate 215a of the gate structures 215. The first metal contact hole 241a is corresponding to the first gate 215a while the second metal contact hole 241b and the third metal contact hole 241c are respectively corresponding to the second P-body region 220b and the third P-body region 220c. Then, an ion inplantation process is carried out to form P+ heavily-doped regions 221 at bottom of contact 241b and 241c.

Referring to FIG. 2F, the metal contact holes 241a, 241b, and 241c can be filled with tungsten metal 237 to form the metal contact plugs 237a, 237b, and 2371c respectively. Besides tungsten metal, aluminum metal or copper metal is used as the contact plug or the front metal layer of the trench MOSFET. After etch back of the contact metal 237, a metal layer Ti/Aluminum alloys 260 is deposited on the insulating layer 230, the first contact plug 237a, the second contact plug 237b, and the third contact plug 237c, and the metal layer 260 comprises a first metal layer region 260a and a second metal layer region 260b which are separated and are metal connections of the trench MOSFET. The first metal layer region 260a is corresponding to connection of the first gate 215a, and the second metal layer region 260b is corresponding to connection of both the source 225 and the P-body 220.

Referring to FIG. 2F, the MOSFET structure with guard ring of the present invention has a MOSFET structure comprises the N+ doped substrate 200, the N-type doping epi layer region 205, the plurality of trenches 206, the plurality of gate structure 215, the gate oxide layer 210, the plurality of P-body regions 220, the plurality of P+ heavily-doped regions 221, the plurality of N+ doping regions 225, the insulating layer 230, the plurality of contact metal plugs (237a, 237b, and 237c), the metal layer 260, and the guard ring 270. The metal layer 260 comprising the first metal layer region 260a and the second metal layer region 260b is formed on the top of the MOSFET structure, and the first metal layer region 260b and the second metal layer region 260a are formed as the source metal, and the gate and field plate metal of the MOSFET, respectively. The gate structure 215 comprising the first gate 215a, the second gate 215b, and the third gate 215c which are covered the gate oxide layer 210 and are filled in the trenches 260 to be used as the gate of the MOSFET. The insulating layer 230 is formed between the metal layer 260 and the gate structure 215 for insulating, and the contact metal plugs 237a, 237b, and 237c are penetrated through the insulating layer 230 and contacted with the metal layer 260. Although the MOSFET structure of the present invention has the partial structure which is similar to prior arts, the guard ring 270 is particularly different from the prior arts. The guard ring 270 wraps around the first contact plug 237a and the first gate 215a underneath the first gate 215a while the first metal layer region 260a of the metal layer 260 covers the first contact plug 237a and the first gate 215a. A part of the P+ heavily-doped regions 221 are formed at the bottom of the second gate 215b while the other P+ heavily-doped regions 221 are formed at the bottom of the third gate 215c.

Referring to FIG. 2F again, according to the embodiment said above, the guard ring 270 can wrap around the first contact plug 237a, the second contact plug 237b and the first gate 215a underneath the first gate 215a while the first metal layer region 260a and the second metal layer region 260b of the metal layer 260 covers the first contact plug 237a, and the second contact plug 237b, respectively.

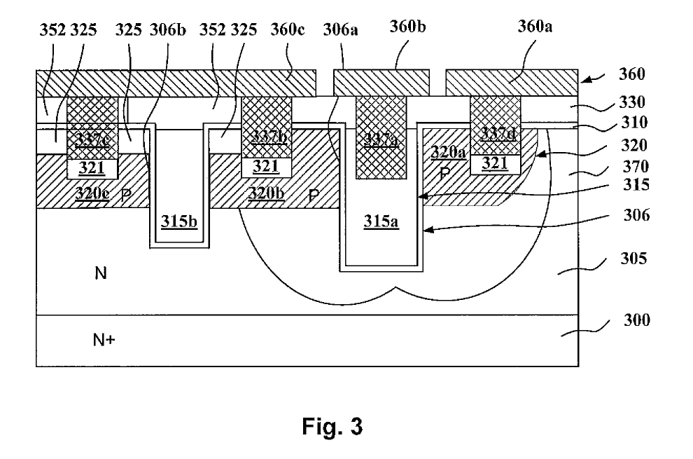

Referring to FIG. 3, a second embodiment of the present invention, the MOSFET structure with guard ring of the present invention is similar to the first embodiment of the present invention and has a MOSFET structure comprises a N+ doped substrate 300, a N-type doping epi layer region 305, a plurality of trenches 306, a plurality of gate structure 315, a gate oxide layer 310, a plurality of P-body regions 320, a plurality of P+ heavily-doped regions 321, a plurality of N+ doping regions 325, a insulating layer 330, a plurality of contact metal plugs (337a, 337b, 337c, and 337d), a plurality of metal layer 360, and a guard ring 370. The metal layer 360 comprising a first metal layer region 360a, a second metal layer region 360b, and a third metal layer 360c is formed on the top of the MOSFET structure, and the first metal layer region 360a, the second metal layer region 360b, and the third metal layer 360c are formed as the source metal, the gate runner, and the field plate metal of the MOSFET respectively. The gate structure 315 comprises the first gate 315a, and the second gate 315b which are covered the gate oxide layer 310 and are filled in the trenches 360 to be used as a gate of the MOSFET. The insulating layer 330 is formed between the metal layer 360 and the gate structure 315 for insulating, and the contact plugs 337a, 337b, 337c, and 337d are penetrated through the insulating layer 330 and contacted with the metal layer 360 respectively. Although the MOSFET structure of the present invention has a partial structure which is similar to prior arts, the guard ring 370 is particularly different from the prior arts. The guard ring 370 wraps around the contact plug 337a, the contact plug 337d and the first gate 315a underneath the first gate 315a while the first metal layer region 360a and the second metal layer region 360b of the metal layer 360 covers the contact plug 337d and the contact plug 337a, respectively.

Referring to FIG. 3 again, according to the embodiment said above, the guard ring 370 can wrap around the contact plug 337a, the contact plug 337b, the contact plug 337d, and the first gate 315a underneath the first gate 315a while the first metal layer region 360a, the second metal layer region 360b, and the third metal layer 360c of the metal layer 360 covers the contact plug 337a, the contact plug 337b, the contact plug 337d, and the first gate 315 on another way.

Although various embodiments are specifically illustrated and described herein, it will be appreciated that modifications and variations of the present invention are covered by the above teachings and are within the purview of the appended claims without departing from the spirit and intended scope of the invention.

What is claimed is:

1. A trench MOSFET structure with a guard ring near a termination area for breakdown voltage enhancement, comprising:
a substrate comprising an epi layer region on a top thereof,
a plurality of source and body regions formed in the epi layer;
a metal layer comprising a plurality of metal layer regions which are connected to respective source and body, and trench gate regions forming metal connections of the MOSFET;
a plurality of contact metal plugs connected to respective metal layer regions;
a plurality of gate structure filled with polysilicon formed on top of the epi layer;
an insulating layer deposited on the epi layer formed underneath the metal layer with a plurality of metal contact holes therein for contacting respective source and body regions; and
the guard ring wrapping around the trench gates which have wider trench width than those in active area, and the contact metal plug connecting to the top of the metal layer.

2. The trench MOSFET structure with the guard ring as claimed in claim 1, wherein the MOSFET structure comprises a plurality of transistors formed in a N-type doping epi region on the heavily doped N-type substrate.

3. The trench MOSFET structure with the guard ring as claimed in claim 1, wherein the MOSFET structure comprises a plurality of transistors formed in a P-type doping epi region on the heavily doped P-type substrate.

4. The trench MOSFET structure with the guard ring as claimed in claim 1, wherein the insulating layer is made of silicon dioxide layer or combination of silicon dioxide and silicon nitride layer.

5. The trench MOSFET structure with the guard ring as claimed in claim 1, wherein heavily-doped regions are disposed at the bottoms of the contact plugs.

6. The trench MOSFET structure with the guard ring as claimed in claim 1, wherein the gate oxide layer in trench gates is single oxide of which oxide thickness nearly uniform along trench sidewall and bottom.

7. The trench MOSFET structure with the guard ring as claimed in claim 1, wherein the gate oxide layer at the bottoms of trench gates has a significant larger thickness than trench sidewall so as to reduce the capacitance of the gate oxide layer.

8. The trench MOSFET structure with the guard ring as claimed in claim 1, wherein the metal layer comprises a first metal layer region and a second metal layer region which are both formed on the top of the MOSFET structure to be the source metal, and the gate and field plate metal of the MOSFET respectively; and the guard ring wrapping around the gates underneath the second metal layer region of the metal layer.

9. The trench MOSFET structure with the guard ring as claimed in claim 8, wherein the gate structure comprises narrow trench gate in active area as the gates of the MOSFET for current conduction and wide trench gate near termination area for trench gate contact to top metal through contact metal plug; the narrow trench gate is corresponding to the first metal layer region (source metal), and the wide trench gate is corresponding to the second metal layer region (the trench gate and field plate); and the guard ring wrapping around the wide trench gate underneath the second metal layer region of the metal layer.

10. The trench MOSFET structure with the guard ring as claimed in claim 1, wherein the metal layer comprises a first metal layer region, a second metal layer region and the third metal layer which are formed on the top of the MOSFET structure to be the source metal, the gate metal and field plate metal of the MOSFET respectively; and the guard ring wrapping around the wide trench gates underneath the gate metal layer region of the metal layer.

11. The trench MOSFET structure with the guard ring as claimed in claim 1, wherein the trench gate having contact metal plug is deeper and wider than the other gate.

12. A method for manufacturing a MOSFET structure with a guard ring, comprising the following steps:
providing an epi layer on a heavily doped substrate;
forming a plurality of trenches in the epi layer;
covering a gate oxide layer on sidewalls and a bottom of the trenches;
forming a conductive layer in the trenches to be used as a gate of MOSFET;
forming a guard ring near by termination wrapping around the trench gates, which is used for gate metal contact;
forming a plurality of body and source regions in the epi layer; forming an insulating layer on the epi layer;
forming a plurality of contact openings in the insulating layer and the source and body regions;
forming contact metal plugs in the contact openings to directly contact with both source and body regions, and a metal layer on the insulating layer.

13. The method as claimed in claim 12, wherein the MOSFET structure comprises a plurality of transistors formed in a N-type doping epi region on the heavily doped N-type substrate.

14. The method as claimed in claim 12, wherein the MOSFET structure comprises a plurality of transistors formed in a P-type doping epi region on the heavily doped P-type substrate.

15. The method as claimed in claim 12, wherein the insulating layer is made of silicon dioxide layer or combination of silicon and silicon nitride layer.

16. The method as claimed in claim 12, wherein heavily-doped regions are disposed at the bottoms of the contact metal plugs.

17. The method as claimed in claim 12, wherein the gate oxide layer in trench gates is single oxide of which oxide thickness nearly uniform along trench sidewall and bottom.

18. The method as claimed in claim 12, wherein the gate oxide layer at the bottoms of trench gates has a significant larger thickness than trench sidewall so as to reduce the capacitance of the gate oxide layer.

19. The method as claimed in claim 12, wherein the metal layer comprises a first metal layer region and a second metal layer region which are both formed on the top of the MOSFET structure to be the source metal, and the gate and field plate metal of the MOSFET respectively; and the guard ring wrapping around the gates underneath the second metal layer region of the metal layer.

20. The method as claimed in claim 12, wherein the gate structure comprises narrow trench gate in active area as the gates of the MOSFET for current conduction and wide trench gate near termination area for trench gate contact to top metal through contact metal plug. The narrow trench gate is corresponding to the first metal layer region (source metal), and the wide trench gate is corresponding to the second metal layer region (the trench gate and field plate); and the guard ring wrapping around the wide trench gate underneath the second metal layer region of the metal layer.

21. The method as claimed in claim 12, wherein the metal layer comprises a first metal layer region, a second metal layer region and the third metal layer which are formed on the top of the MOSFET structure to be the source metal, the gate metal and field plate metal of the MOSFET respectively; and the guard ring wrapping around the wide trench gates underneath the gate metal layer region of the metal layer.

22. The method as claimed in claim 12, wherein the trench gate having contact metal plug is deeper and wider than other gates.
